(19) United States
(12) Patent Application Publication
(10) Pub. No.: US 2025/0355616 A1
(43) Pub. Date: Nov. 20, 2025

(54) Device and Method for Adjusting the Volume of an Audio Signal in an Audio System

(71) Applicant: Bayerische Motoren Werke Aktiengesellschaft, Muenchen (DE)

(72) Inventors: Markus BINDER, Landshut (DE); Andreas STICKEL, Muensing (DE); Andrea STUPIGGIA, Deisenhofen (DE)

(21) Appl. No.: 19/209,899

(22) Filed: May 16, 2025

(30) Foreign Application Priority Data
May 17, 2024 (DE) 10 2024 113 882.3

(51) Int. Cl. G06F 3/16

(52) U.S. Cl. CPC G06F 3/165

(57) ABSTRACT

A device for adjusting the volume of an audio signal in an audio system is provided, wherein the audio system has an input for receiving the audio signal from an input source and an output for outputting the audio signal. The device includes a determination unit configured to determine a loudness of the audio signal, and an adjustment unit configured to regulate a level of the audio signal to a target value. The device further includes a damping unit, downstream of the adjustment unit, which is configured to attenuate the audio signal regulated by the adjustment unit by a predetermined damping value based on the determined loudness.

### CROSS REFERENCE TO RELATED APPLICATION

This application claims priority under 35 U.S.C. § 119 from German Patent Application No. 10 2024 113 882.3, filed May 17, 2024, the entire disclosure of which is herein expressly incorporated by reference.

### BACKGROUND AND SUMMARY

The present invention relates to a device for adjusting the volume of an audio signal in an audio system of a motor vehicle, as well as to a motor vehicle with such a device. Furthermore, the present invention relates to a method for adjusting the volume of an audio signal in an audio system of a motor vehicle.

In today's vehicles, audio signals from various audio sources (e.g., radio, external devices via interfaces, etc.) can be played in the vehicle. The volume of the output signal can be set by a user. However, these audio sources—or even the audio signal from a single source—can have different volume levels. As a result, when switching between audio sources or even within a single audio signal (e.g., from one music track to another or even within a single track), the output volume may vary despite the user setting remaining unchanged. This can be compensated for by a function of the audio system designed to balance differences in the audio signal levels. In this case, the level of the input signal is adjusted toward a target value so that all audio signals, especially those from different sources, are played at the same perceived volume level in the vehicle.

However, it has been found that in music tracks with level jumps, this function may equalize the output signal level but cause overshoots that impair sound quality and the listening experience. This means that for tracks containing different levels or level jumps (e.g., a very quiet intro followed by a very loud section), the output signal does not reach the desired target value (target level) directly after a sudden change in the input signal's volume but overshoots it and only then settles to the desired level.

The object of the present invention is therefore to provide a way to output an audio signal with balanced volume, even in the case of abrupt changes in volume level.

This object is achieved by a device for adjusting the volume of an audio signal in an audio system of a motor vehicle, by a motor vehicle with such a device and by a method for adjusting the volume of an audio signal in an audio system of a motor vehicle, in accordance with the independent claim(s).

The device serves to adjust the volume of an audio signal in an audio system of a motor vehicle. The audio system comprises an input for receiving an audio signal from an input source and an output for outputting the audio signal. The audio system can play music or other audio signals (e.g., navigation announcements) from various external or integrated input sources. In this context, an input source may be understood as an audio source via which content such as music or audiobooks, as well as phone calls or navigation announcements, can be output as audio signals. The internal input source, for example a vehicle-integrated input source, may include a radio, a CD player integrated into the audio system, a hard drive integrated into the audio system, or a memory card that is connected via a USB port (e.g., a “USB stick”). The external input source may be connected to the audio system via Bluetooth or an AUX input, for example. Such an external input source may be a smartphone or an MP3 player, for instance.

The audio signals from both the external and internal input sources are played through the speaker system of the audio system. The volume of the audio signal output through the audio system can be adjusted directly in the audio system via a regulator located there.

As previously mentioned, abrupt changes in level can occur between audio signals from different sources or even within a single audio signal. These changes can be mitigated by a determination unit and an adjustment unit of the proposed device. The determination unit is designed to determine a loudness of the audio signal. The loudness of the audio input signal can be measured as an LKFS value (Loudness, K-weighted, relative to full scale). The LKFS value is a loudness standard that enables normalization of audio levels for broadcast and other audio/video transmissions. The measured LKFS value can in particular be understood as the averaged LKFS value, i.e., the value averaged over several short, successive measurements. Considering the full range of music tracks (from very quiet, e.g., classical, to very loud, e.g., rock), the LKFS value typically varies between approximately −14 and −30 (the so-called normal LKFS value range). The determination unit determines the LKFS value at the input of the audio system, i.e., it determines a value that depends on the input audio source and not on the volume setting.

The adjustment unit is configured to then regulate the level of the audio signal to a target value. For example, a target value or target level of −14 dB can be selected. In this way, input signals with levels above the target level are reduced and input signals below the target level are increased. The adjustment speed is usually relatively slow (at 1000 ms) to prevent abrupt volume fluctuations. In the case of sudden loudness changes—for example in music tracks with level jumps (e.g., a very quiet intro followed by a loud band entry)—this adjustment unit alone does not operate optimally: the level of the audio signal is very low at the beginning (intro). Consequently, the adjustment unit increases the level of the audio signal. Following the intro, there is an abrupt level jump when the band starts playing. Since the adjustment unit operates slowly, it is still in the process of maximum amplification at the moment of the level jump. Afterwards, the level of the audio signal is slowly decreased by the adjustment unit. The band's entry is therefore reproduced much louder than the passage a few seconds later, creating an undesired overshoot.

Although the adjustment unit reliably compensates for changes in volume or loudness by adjusting the audio signal level accordingly, overshoots occur with this control mechanism, as described above. These can now be avoided by further including a damping unit in the device, which is downstream of the adjustment unit and is configured to attenuate the audio signal regulated by the adjustment unit by a predetermined damping value based on the determined loudness. Since the damping value depends on the loudness of the audio signal, the damping unit can attenuate a high level with a different damping value than a low level. In this way, strong level increases caused by the adjustment unit can be mitigated by the damping unit. Because the damping unit operates independently of the adjustment unit, it can provide a faster response time and thereby compensate for the overshoots described above, in particular.

According to one embodiment, the damping unit is configured to compare the determined loudness with stored loudness values and to select the predetermined damping value based on this comparison. In particular, the device may include a memory unit in which predetermined damping values are stored together with associated loudness values. In this way, a very fast and simple damping of the output signal from the adjustment unit can be achieved with minimal computational capacity. Since the corresponding damping values can be easily read from the memory unit, the overshoots described above can be quickly attenuated.

For example, loudness values and damping values may be stored in a table. Such a table may look as follows:

| Loudness value | Damping value |
|---|---|
| −30 | 2 |
| −25 | 3 |
| −20 | 4 |
| −15 | 5 |
| . . . | . . . |

The damping values are merely exemplary, and other damping values may be provided. It is also possible for multiple tables to be stored, and for the table or the corresponding damping values to be selected depending on whether strong or mild damping is to be achieved. Strong damping, i.e., a high damping value, means that the occurring overshoots are heavily dampened and thus are no longer present or barely noticeable. Mild damping, i.e., a low damping value, means that while the overshoot is dampened, it is still present. The corresponding selection of the table may be made, for example, by a user input that determines the type of damping—i.e., strong, mild, or also intermediate stages.

For example, damping values for different damping levels (strong damping, mild damping, etc.) may be stored in the memory unit, for instance in the form of the tables described above. In this case, the damping unit may be configured to select a damping level and the associated damping values based on a user input.

The damping unit may further be configured to determine a distance between the target value and the level value of the regulated audio signal and, if the distance is less than a threshold value, to terminate the damping of the audio signal regulated by the adjustment unit. The threshold value may, in particular, be zero. In this way, damping may be omitted if, for example, there is no abrupt volume change or if the adjustment unit has already completed the regulation to the target value.

According to another embodiment, the damping unit is configured to dampen the audio signal regulated by the adjustment unit within a predetermined time. Preferably, the predetermined time is such that the damping unit dampens the audio signal faster than the time required by the adjustment unit to regulate the audio signal to the target value. In this way, the overshoots described above can be dampened more quickly than would be possible with the adjustment unit alone.

The damping unit may be configured to select the predetermined time based on a user input. This allows the user to choose how quickly occurring overshoots should be dampened. A short predetermined time, e.g., 10 ms, means that occurring overshoots are quickly dampened and are thus brief. A longer predetermined time, e.g., 30 ms, means that occurring overshoots are dampened more slowly and therefore last longer.

According to another aspect, a motor vehicle with a device as described above for adjusting the volume of an audio signal is proposed.

According to another aspect, a method for adjusting the volume of an audio signal in an audio system is proposed, wherein the audio system receives the audio signal from an input source and outputs it at an output, and the method comprises determining a loudness of the audio signal and regulating a level of the audio signal to a target value. The method further comprises dampening the regulated audio signal by a predetermined damping value based on the determined loudness.

The embodiments and features described for the proposed device apply correspondingly to the proposed method.

Furthermore, a computer program product is proposed that includes a program code configured to cause a computer to perform the method as described above.

A computer program product, such as a computer program means, may for example be provided or delivered as a storage medium, such as a memory card, USB stick, CD-ROM, DVD, or also in the form of a downloadable file from a server in a network. This may be done, for instance, in a wireless communication network by transmitting a corresponding file containing the computer program product or the computer program means.

Other possible implementations of the invention also include combinations of features or embodiments previously or subsequently described with respect to the exemplary embodiments, even if not explicitly mentioned. A person skilled in the art will also add individual aspects as improvements or enhancements to the respective basic form of the invention.

Additional advantages and advantageous embodiments are indicated in the description, the drawings, and the claims. In particular, the combinations of features stated in the description and drawings are purely exemplary, such that the features may also be present individually or in other combinations.

The invention will now be described in more detail based on exemplary embodiments shown in the drawings. The embodiments and the feature combinations shown in the embodiments are purely exemplary and are not intended to define the scope of protection of the invention. The scope is defined solely by the appended claims.

### BRIEF DESCRIPTION OF THE DRAWINGS

FIG. 1: a schematic block diagram of a device for adjusting the volume of an audio signal in an audio system;

FIGS. 2A and 2B: example diagrams of audio signals with different damping values; and

FIGS. 3A and 3B: example diagrams of audio signals with different damping times.

### DETAILED DESCRIPTION OF THE DRAWINGS

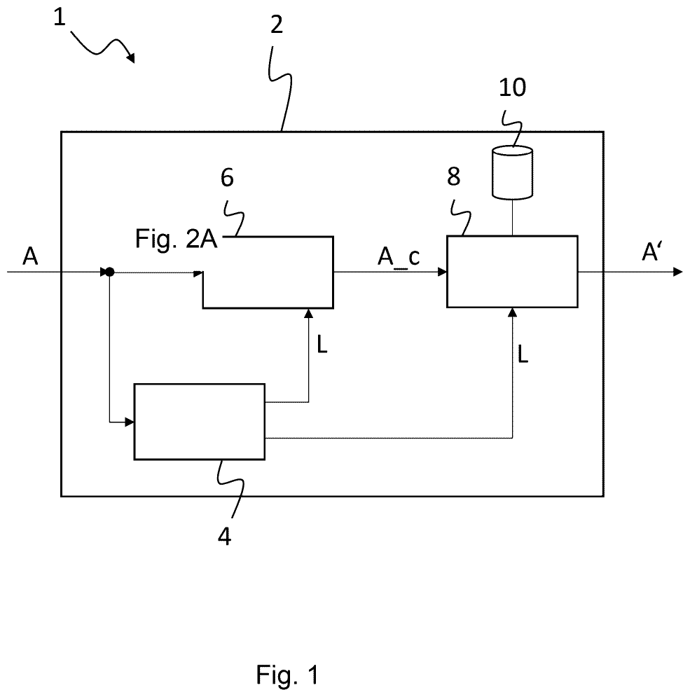

FIG. 1 shows an audio system 1 with a device 2 for adjusting the volume of an audio signal A in the audio system 1. The audio system 1 comprises an input (not shown) for receiving the audio signal A from an input source and an output (not shown) for outputting the audio signal A′.

As explained above, the input source may be any audio input source, such as a radio or external devices (like a smartphone), etc. In each case, an audio signal is received via the input source that may vary in volume (for example, when switching input sources or even within the audio signal from a single input source). To avoid such volume variation in the output signal A′, the device 2 includes a determination unit 4, which is configured to determine a loudness L of the audio signal A. Based on this determined loudness L, an adjustment unit 6 can then regulate the level of the audio signal A to a target value. This target value may be pre-set by a user, for example.

However, if the audio signal A contains abrupt changes in loudness L or sudden level jumps, the adjustment unit 6 cannot compensate for these rapid, abrupt changes quickly enough, as it performs slow regulation. The regulated audio signal A_c will therefore initially be louder than desired and will only subsequently be regulated to the desired level.

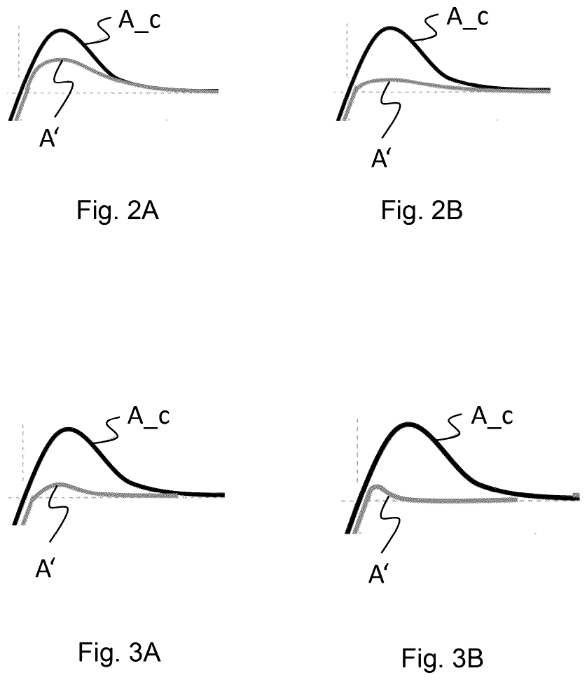

For example, the intro of a music track may be very quiet. The adjustment unit 6 therefore increases the level of the audio signal A. Following the intro, there is an abrupt level jump when the band starts playing. Since the adjustment unit 6 regulates slowly, it is still in the state of maximum amplification at the time of the level jump. The level of the input source is then gradually reduced by the adjustment unit 6. The band's entry is thus played back significantly louder than the passage a few seconds later. This results in an overshoot of the audio signal A_c, as shown in FIGS. 2A, 2B, 3A, and 3B.

To avoid such overshoots, the device 2 includes a damping unit 8 that is downstream of the adjustment unit 6. This means that the damping unit 8 is used to dampen the audio signal A_c, already regulated by the adjustment unit 6, when necessary—particularly in the case of the overshoots described above. Based on the determined loudness L, the damping unit 8 attenuates the audio signal A_c regulated by the adjustment unit 6 by a predetermined damping value, and then outputs the regulated and damped audio signal A′.

The damping unit 8 is intended to quickly attenuate abrupt level jumps. The damping value can be retrieved from a memory unit 10, for example, based on a table depending on the input loudness L.

As shown in FIGS. 2A, 2B, 3A, and 3B, a small overshoot may still occur in the audio signal A′ even when the damping unit 8 is used. However, this overshoot is very brief and smaller in magnitude, and either imperceptible or barely noticeable. The damping unit 8 reliably absorbs level jumps to maintain greater stability in overall dynamics.

Both the damping value and the time over which the damping is performed can be configured by a user or retrieved accordingly from the memory unit 10. The selection of these values affects the strength of the damping and the response time of the damping unit 8. For example, if a smaller damping value is chosen (FIG. 2A), the overshoot will be less attenuated than with a larger damping value (FIG. 2B). The same applies to the time: with a larger time value, the overshoot lasts longer (FIG. 3A) than with a smaller time value (FIG. 3B).

The device described above thus enables an optimized and improved compensation of level differences between audio sources. The damping unit provides rapid damping of abrupt level jumps, thereby avoiding or at least reducing overshoots.

### REFERENCE SIGNS

1 Audio system
2 Device
4 Determination unit
6 Adjustment unit
8 Damping unit
10 Memory unit
A Input audio signal
A_c Audio signal regulated by the adjustment unit
A Regulated and damped output audio signal
L Loudness value

What is claimed is:

1. A device for adjusting a volume of an audio signal in an audio system, wherein the audio system has an input for receiving the audio signal from an input source and an output for outputting the audio signal, the device comprising:
a determination unit, which is configured to determine a loudness of the audio signal;
an adjustment unit, which is configured to regulate a level of the audio signal to a target value; and
a damping unit, which is downstream of the adjustment unit, and which is configured to attenuate the audio signal regulated by the adjustment unit by a predetermined damping value based on the determined loudness.

2. The device according to claim 1, wherein
the damping unit is configured to compare the determined loudness with stored loudness values and to select the predetermined damping value based on said comparison.

3. The device according to claim 2, further comprising:
a memory unit in which predetermined damping values associated with corresponding loudness values are stored.

4. The device according to claim 3, wherein
damping values for various damping levels are stored in the memory unit, and
the damping unit is configured to select a damping level and the associated damping values based on a user input.

5. The device according to claim 1, wherein
the damping unit is configured to determine a distance between the target value and the level of the regulated audio signal, and to terminate the damping of the audio signal regulated by the adjustment unit when the distance is less than a threshold value.

6. The device according to claim 5, wherein the threshold value is zero.

7. The device according to claim 1, wherein
the damping unit is configured to attenuate the audio signal regulated by the adjustment unit within a predetermined time.

8. The device according to claim 7, wherein
the damping unit is configured to select the predetermined time based on a user input.

9. A motor vehicle comprising a device for adjusting the volume of an audio signal according to claim 1.

10. A method for adjusting a volume of an audio signal in an audio system, the method comprising:
receiving, by the audio system, the audio signal from an input source;
determining a loudness of the received audio signal and regulating a level of the received audio signal to a target value;
attenuating the regulated audio signal by a predetermined damping value based on the determined loudness; and
outputting, by the radio system, the attenuated regulated audio signal.
